(19) United States
(12) Patent Application Publication
(10) Pub. No.: US 2005/0275057 A1
(43) Pub. Date: Dec. 15, 2005

(54) Schottky diode with dielectric isolation

(76) Inventors: Marc L. Breen, Hollywood, CA (US); Jerry R. Kukulka, Santa Clarita, CA (US); Deanna McMullin, Simi Valley, CA (US); Dmitri Krut, Encino, CA (US); David E. Joslin, Valley Village, CA (US)

Correspondence Address: INGRASSIA FISHER & LORENZ, P.C., 7150 E. CAMELBACK, STE. 325, SCOTTSDALE, AZ, 85251, US

(21) Appl. No.: 10/869,071

(22) Filed: Jun. 15, 2004

(51) Int. Cl. H01L 29/93

(52) U.S. Cl. 257/480

(57) ABSTRACT

Methods and apparatus are provided for configuring a Schottky diode with reduced reverse leakage current. The apparatus comprises a dielectric layer interposed between a Schottky metal layer and a Schottky semiconductor layer. The dielectric layer is patterned to allow a limited amount of direct contact between the metal layer and the semiconductor layer, thereby controlling the size and configuration of the Schottky diode active area. Limiting the amount of active diode area can reduce the probability of leakage current due to localized shunts. Moreover, the dielectric layer can also be configured to inhibit diffusion from the metal layer to the semiconductor layer. Accordingly, the reverse leakage current of a Schottky diode with dielectric isolation is typically lower than that of a similar diode with no dielectric layer.

### TECHNICAL FIELD

The present invention generally relates to a Schottky diode, and more particularly relates to a Schottky diode with dielectric isolation.

### BACKGROUND

The Schottky diode is a semiconductor device that is currently used in a wide variety of applications. Unlike a conventional semiconductor diode, which is typically configured as a semiconductor-to-semiconductor junction, a Schottky diode is generally configured as a metal-to-semiconductor junction and typically functions as a majority carrier device. Schottky diodes generally have a low turn-on forward voltage (V_{f}) characteristic as compared to conventional semiconductor diodes, and this characteristic can be advantageous for many types of applications, particularly those involving relatively high levels of current density. One potential disadvantage of the Schottky diode is the typical reverse leakage current characteristic (Iᵣ), which can be problematic for certain types of applications.

For example, in a typical Schottky diode configuration 100, as depicted in FIG. 1, a Schottky metal layer 102 is deposited directly on the surface of a doped semiconductor material 104 that is typically disposed on a more highly doped semiconductor material 106. An interconnect 108 is typically welded to metal layer 102 to provide an electrical path to an external circuit (not shown). In this type of configuration, the Schottky diode “active area”, which at the junction of metal layer 102 and semiconductor material 104, typically encompasses the entire contact surface of metal layer 102 and semiconductor material 104. The size of metal layer 102 is generally configured to be at least large enough to accommodate the attachment of interconnect 108. However, the larger the metal-to-semiconductor (diode) active area, the greater the likelihood of localized shunt paths (leakages) 110 due to semiconductor imperfections and/or residual surface materials. In addition, there is typically a risk of diffusion in area 103 from metal layer 102 through semiconductor material 104, as a result of the heat generated during the interconnect 108 welding process in the area 112 between interconnect 108 and metal layer 102. As such, the presence of shunt path leakages and heat-related diffusion in a conventional Schottky diode configuration can typically lead to an increase in the reverse leakage current (Iᵣ) characteristic.

A Schottky diode application of current interest utilizes the Schottky diode as a bypass device for a solar cell structure. Typically, solar cells are connected in a series string, and if a cell within the string becomes shaded while the other cells are still illuminated, the shaded cell can be forced into reverse bias breakdown in order to conduct the current flowing through the series string. To mitigate this problem, a Schottky diode can be connected in reverse polarity across each solar cell to provide a bypass current path for a shaded cell within an illuminated string.

Two important electrical characteristics for a solar cell bypass diode are the turn-on forward voltage (V_{f}) and the reverse leakage current (Iᵣ). It is generally desirable to maintain a relatively low forward voltage (V_{f}) in order to minimize thermal effects when the bypass diode is turned on. It is also generally desirable to achieve as low reverse leakage current (Iᵣ) as possible in the bypass diode in order to maximize the forward current flow through the associated solar cell. As noted previously, a Schottky diode typically exhibits a relatively low forward voltage (V_{f}) characteristic, but may tend toward a relatively high level of reverse leakage current (Iᵣ) that can degrade the performance of the bypassed cell.

Accordingly, it is desirable to provide an exemplary Schottky diode configuration that exhibits a relatively low turn-on forward voltage (V_{f}) and a relatively low level of reverse leakage current (Iᵣ), as compared to a typical Schottky diode. In addition, it is desirable to provide a method of fabricating the exemplary Schottky diode as a bypass diode in a solar cell structure. Furthermore, other desirable features and characteristics of the present invention will become apparent from the subsequent detailed description and the appended claims, taken in conjunction with the accompanying drawings and the foregoing technical field and background.

### BRIEF SUMMARY

According to various exemplary embodiments, devices and methods are provided for improving the reverse leakage current characteristic of a Schottky diode. One exemplary embodiment comprises a Schottky diode with dielectric isolation. A dielectric material with at least one opening is typically deposited on the surface of a Schottky semiconductor layer, to act as an isolation layer between a Schottky metal layer and the Schottky semiconductor layer. The Schottky metal layer is disposed over the dielectric material and through the opening(s) of the dielectric material to the Schottky semiconductor layer, thus forming a Schottky junction diode active area, where the size and configuration of the active area are dependent on the opening(s) in the dielectric layer.

In another exemplary embodiment, a Schottky diode with dielectric isolation can be configured as a bypass diode for a solar cell. The solar cell and Schottky bypass diode are typically connected in parallel reverse polarity, and generally share a common substrate. The Schottky bypass diode typically includes a patterned dielectric layer disposed between a Schottky metal layer and a Schottky semiconductor layer. The dielectric layer pattern enables a limited portion of the Schottky metal layer to form a Schottky junction diode active area on the surface of the Schottky semiconductor layer.

### BRIEF DESCRIPTION OF THE DRAWINGS

The present invention will hereinafter be described in conjunction with the following drawing figures, wherein like numerals denote like elements, and

FIG. 1 is an illustration of a typical Schottky diode configuration;

FIG. 2 is an illustration of an exemplary Schottky diode configuration with dielectric isolation;

FIG. 3 is a plan view illustration of an exemplary Schottky diode configuration with dielectric isolation;

FIG. 4 is an illustration of an alternate embodiment of an exemplary Schottky diode configuration with dielectric isolation;

FIG. 5 is a graphic presentation of exemplary test results of Schottky diode reverse leakage current with and without dielectric isolation.

FIG. 6 is a simplified diagram of an exemplary monolithic solar cell/bypass Schottky diode configuration;

FIG. 7 is an exemplary diagram of a series string of illuminated solar cell/bypass diodes in forward bias mode; and

FIG. 8 is an exemplary diagram of a string of two illuminated solar cell/bypass diodes in forward bias mode in series with one shaded solar cell/bypass diode in reverse bias mode.

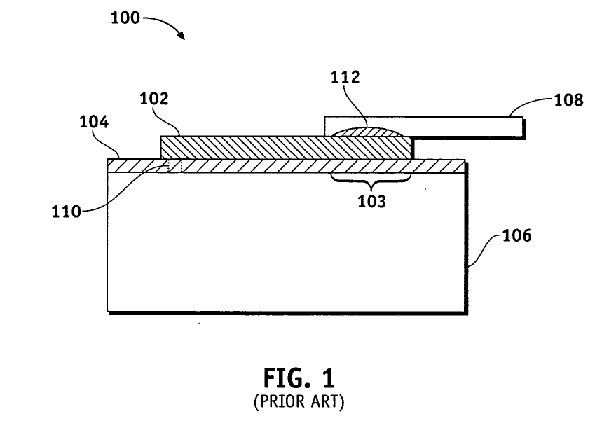

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Various embodiments of the present invention pertain to the area of Schottky diode configuration. In an exemplary embodiment, a dielectric isolation layer is disposed between a metal layer and a semiconductor layer to form a Schottky diode with improved (i.e., reduced) reverse leakage current (Iᵣ) characteristics. The exemplary dielectric isolation layer is typically patterned to allow a limited amount of metal contact area at the surface of the semiconductor layer, thereby reducing the probability of localized shunt leakage paths that typically increase the reverse leakage current (Iᵣ) of the device. The exemplary dielectric isolation layer is also typically configured to provide physical insulation from the effects of interconnect welding, in order to minimize diffusion under the weld area that would also tend to increase the level of the reverse leakage current (Iᵣ).

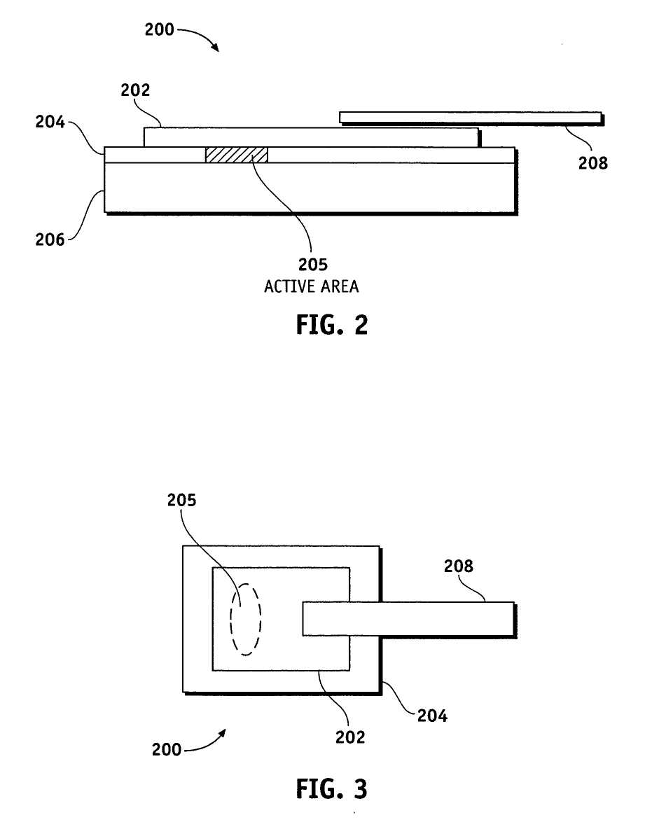

According to an exemplary embodiment of a Schottky diode 200 with dielectric isolation, as shown in FIG. 2, a Schottky metal layer 202 is partially insulated from a Schottky doped semiconductor material 206 by a dielectric isolation layer 204. In this exemplary embodiment, dielectric isolation layer 204 is patterned with an aperture 205 that allows a portion of metal layer 202 to contact the semiconductor 206. Aperture 205 defines the Schottky junction or active area between metal layer 202 and semiconductor 206. As such, the size and configuration of the Schottky active area can be controlled with the pattern of dielectric layer 204. Also shown in FIG. 2 is an interconnect 208, which is typically welded to metal layer 202. However, other interconnect configurations are within the purview of the present invention.

FIG. 3 is a plan view illustration of exemplary Schottky diode 200. The size, shape and location of the active area defined by the aperture 205 are merely exemplary, and are generally determined by a number of considerations, as will be described more fully below. The active area is generally configured so that it is not overlapped by interconnect 208, to avoid possible damage to the active area when interconnect 208 is welded to metal layer 202.

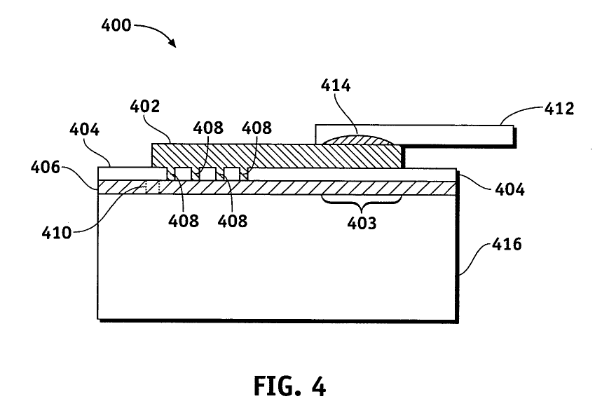

Another exemplary embodiment of a Schottky diode 400 configured with dielectric isolation is depicted in FIG. 4. In this embodiment, a metal layer 402 is disposed over a dielectric layer 404 with multiple apertures 408. A portion of metal layer 402 is thereby enabled to contact a semiconductor layer 406 through apertures 408, where semiconductor layer 406 is typically disposed on a more highly doped semiconductor substrate 416. The portion of metal layer 402 that contacts the surface of semiconductor layer 406 through apertures 408 forms a limited Schottky active area. This limited Schottky active area typically reduces the probability that metal layer 402 will come into direct contact with a defect, such as a shunt leakage path 410, or other type of semiconductor imperfection. Moreover, dielectric layer 404 typically acts as an insulator between metal layer 402 and semiconductor layer 406 under the weld area 414 of an interconnect 412. As such, the likelihood of metal diffusion from metal layer 402 through semiconductor layer 406 to a semiconductor substrate 416 in area 403 is generally reduced significantly. In addition, dielectric isolation layer 404 can be configured to provide protection at the perimeter of Schottky diode 400 against environmental contamination.

Apertures 408 are typically defined by patterning dielectric layer 404 prior to the deposition of metal layer 402. The patterning of dielectric layer 404 can be implemented by a photolithographic, masking or other appropriate technique. The size and configuration of apertures 408 are generally determined by consideration of a number of parameters and factors, such as forward current, forward voltage, reverse leakage current, interconnect weld area, overall device size, manufacturability, and so forth. For example, a larger active area generally results in a lower forward voltage, but is typically more vulnerable to leakage currents. Conversely, a smaller active area generally reduces the leakage current possibilities, but also tends to limit the forward current capability. Moreover, it is generally desirable to configure an active area so that it is not overlapped by an interconnect weld area. Based on these and other considerations, such as device size and manufacturability, the pattern imposed on a dielectric layer 404 is generally a configuration that is considered to be optimal for a specific Schottky diode application.

As noted in the Background, Schottky diodes can be used as bypass devices for solar cells. In this type of application, the efficiency of the solar cell can be adversely affected by the amount of reverse leakage current carried by the bypass diode. Therefore, it is generally desirable to limit the size of a Schottky bypass diode active area in order to minimize potential leakage paths, while still maintaining sufficient metal-to-semiconductor contact area to support the solar cell forward current. For example, in one solar cell/bypass diode application, a Schottky active area of approximately six thousand (6,000) square microns was found to be an appropriate size for achieving the desired levels of both forward current and reverse leakage current.

It can be appreciated that the active area size and configuration of an exemplary Schottky diode can be “tuned” by reconfiguring the aperture or apertures in the dielectric layer for a particular application. For example, the active area can be made larger to support an increased current load without necessarily changing the interconnect weld footprint. Alternately, the interconnect weld footprint can be increased to accommodate various interconnect designs without necessarily changing the size of the active area. As stated previously, it is generally desirable to avoid overlapping the active area with the interconnect weld area, and this consideration is typically a factor in the determination of the shape, size and location of the active area.

Dielectric layer 404 is typically fabricated from a thin film (e.g., in the approximate range of about two hundred (200) angstroms to one (1) micron) of dielectric material. Materials possessing these characteristics can include, but are not limited to, individual layers or combinations of silicon dioxide, silicon monoxide, silicon nitride, polyimide, aluminum oxide, titanium dioxide, and tantulum pentoxide. Dielectric layer 404 can provide isolation not only from a shunt defect 410 and from welding-related diffusion, but can also be configured to protect the perimeter of Schottky diode 400 from environmental contamination.

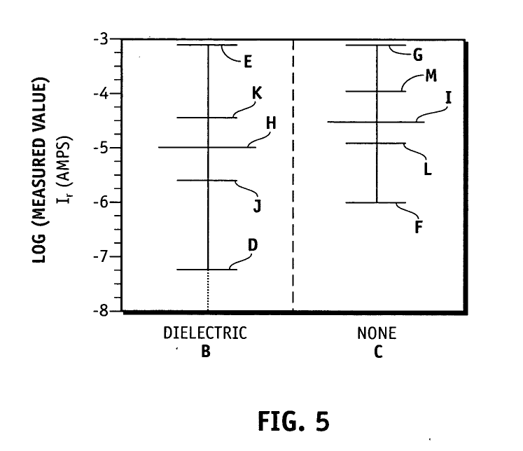

The effectiveness of dielectric layer 404 in reducing reverse leakage current (Iᵣ) is illustrated in the test results presented in FIG. 5. Two populations (B, C) of Schottky diode test samples were evaluated, where populations B and C were each approximately three hundred and thirty (330) samples. The population B samples included a dielectric layer, such as layer 204 in FIG. 2 or layer 404 in FIG. 4, while the population C samples did not have a dielectric layer. Lines D and F represent tenth (10^{th}) percentiles, respectively, for populations B and C, and lines E and G represent ninetieth (90^{th}) percentiles, respectively, for populations B and C. In similar fashion, levels J and L represent twenty-fifth (25^{th}) percentiles and levels K and M represent seventy-fifth (75^{th}) percentiles. The vertical axis scale in FIG. 5 represents logarithmic values of reverse leakage current (Iᵣ) at a test sample bias voltage of approximately minus three and eight tenths (−3.8) volts. For example, the “−5” marker on the vertical axis represents a reverse leakage current (Iᵣ) value of 10⁻⁵ amperes. Levels H and I represent the group mean values of reverse leakage current (Iᵣ) for the populations B and C, respectively. It is clear from the chart in FIG. 5 that the diode test samples with dielectric isolation of population B exhibit a group mean level (H) that is significantly lower than the group mean level (I) of the diode test samples with no dielectric of population C. Therefore, the test data indicate that the addition of an appropriately configured dielectric layer to a Schottky diode device can reduce the inherent reverse leakage current (Iᵣ) characteristic. It can also be noted that the broader distribution of reverse leakage current (Iᵣ) values for population B, as compared to population C, may be due to the skewing of population B toward ultra low levels of reverse leakage current (Iᵣ) (e.g., in the microampere range).

As noted above, an exemplary Schottky diode with reduced reverse leakage current (Iᵣ) can be advantageous for a solar cell/bypass diode application. In this type of application, an exemplary Schottky bypass diode with a dielectric isolation layer can improve the efficiency of an illuminated solar cell, in comparison to a conventional Schottky bypass diode, since more of the forward bias current will flow through the illuminated cell when the bypass diode carries a reduced amount of reverse leakage current.

To provide bypass protection for a solar cell, a Schottky diode is typically connected across the solar cell in reverse polarity. That is, if the solar cell is configured as an n-p junction, the Schottky bypass diode will typically be configured as a p-n junction diode in parallel with the n-p solar cell. If a shaded solar cell in an otherwise illuminated solar cell string becomes reverse biased, the corresponding Schottky bypass diode typically becomes forward biased, and can therefore bypass the string current to prevent the shaded cell from experiencing reverse bias breakdown.

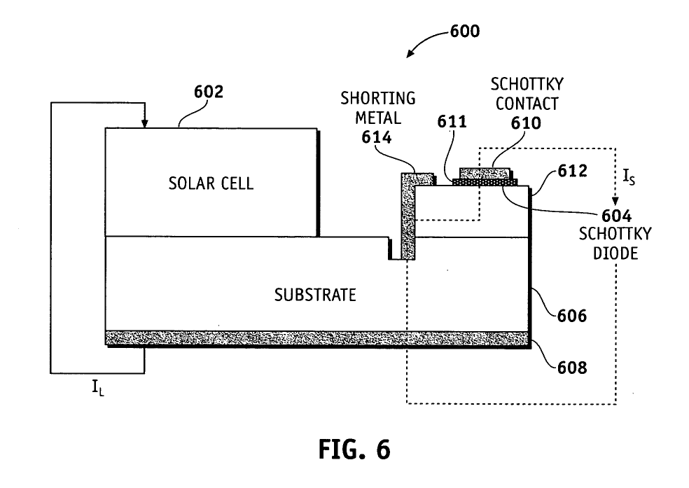

Solar cell bypass diodes have been used in discrete form and, more recently, in monolithic form. An exemplary solar cell/monolithic Schottky bypass diode configuration 600 is illustrated in simplified form in FIG. 6 according to an exemplary embodiment of the present invention. A solar cell 602 and a Schottky diode 604 typically share a common substrate 606 and a common back metallization 608. Schottky diode 604 is typically comprised of a metal contact 610 that is partially isolated from semiconductor material 612 by a patterned dielectric layer 611, in general accordance with the previously described exemplary Schottky diode configurations 200 and 400. Also shown in FIG. 6 is a metal short 614, which is generally used to provide an electrical short circuit around an opposite polarity diode underneath Schottky diode 604. In addition, the solar cell 602 forward current (I_{L}) and the Schottky diode 604 forward current (I_{S}) are each indicated by solid and dashed lines, respectively.

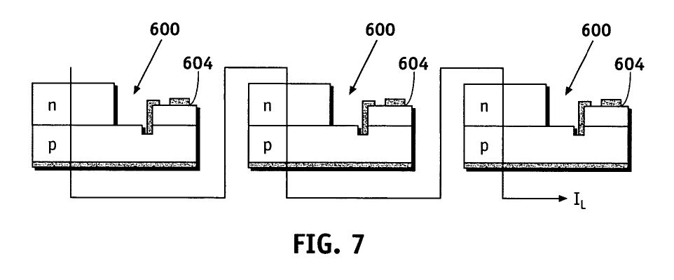

When solar cell structures 600 are connected in a series string and are each illuminated by sunlight, forward current (I_{L}) typically flows from “n” to “p” as illustrated in FIG. 7. In this example, all cells 600 are illuminated and are thus forward biased. As such, the Schottky bypass diodes 604 are reverse biased with respect to forward current (I_{L}) of the illuminated cells, and are effectively non-conducting, except for reverse leakage current. As previously noted, an illuminated solar cell will typically operate more efficiently when the associated Schottky bypass diode includes dielectric isolation, since the dielectric isolation can reduce the inherent level of reverse leakage current (Iᵣ) through the Schottky diode.

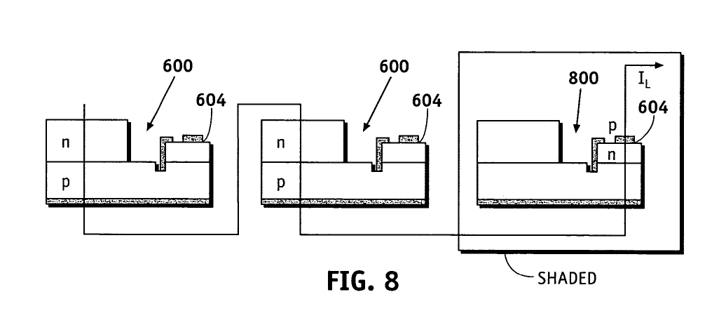

If one of the solar cells 600 in a series string becomes shaded while the other cells are still illuminated as illustrated in FIG. 8, the shaded cell (800) typically becomes reverse biased with respect to the illuminated cells 600. In the absence of a bypass diode, shaded cell 800 would typically be forced into reverse bias breakdown in order to conduct string current I_{L}. Under these conditions, shaded cell 800 can be permanently damaged due to excessive heat generated within the cell. When a Schottky bypass diode 604 is integrated into solar cell structure 800, however, a forward biased path for current (I_{L}) is provided through bypass diode 604, thereby protecting solar cell 800 from reverse bias breakdown.

Accordingly, the shortcomings of the prior art have been overcome by providing an improved Schottky diode configuration. In an exemplary embodiment, a dielectric layer is interposed between the Schottky metal layer and the Schottky semiconductor surface. The dielectric layer is typically patterned to allow a relatively small amount of direct contact between the metal layer and the semiconductor layer. The resulting reduced active diode area can reduce the possibility of localized shunt leakage paths. In addition, the dielectric layer can be configured to inhibit diffusion from the metal layer to the semiconductor layer as a result of an interconnect weld. As such, the reverse leakage current of an exemplary Schottky diode with dielectric isolation is typically lower than that of a conventional Schottky diode with no dielectric isolation.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing the exemplary embodiment or exemplary embodiments. It should be understood that various changes can be made in the function and arrangement of elements without departing from the scope of the invention as set forth in the appended claims and the legal equivalents thereof.

1. (canceled)

2. (canceled)

3. The Schottky diode of claim 28 wherein the dielectric material is configured with a plurality of apertures.

4. (canceled)

5. (canceled)

6. The Schottky diode of claim 28 wherein the dielectric material is comprised of one or more thin film materials having a thickness in the approximate range of two hundred (200) angstroms to one (1) micron.

7. The Schottky diode of claim 6 wherein the thin film material is silicon dioxide.

8. The Schottky diode of claim 6 wherein the thin film material is silicon monoxide.

9. The Schottky diode of claim 6 wherein the thin film material is silicon nitride.

10. The Schottky diode of claim 6 wherein the thin film material is polyimide.

11. The Schottky diode of claim 6 wherein the thin film material is aluminum oxide.

12. The Schottky diode of claim 6 wherein the thin film material is titanium dioxide.

13. The Schottky diode of claim 6 wherein the thin film material is tantulum pentoxide.

14. A method of configuring a Schottky diode with dielectric isolation, comprising the steps of:
a) disposing a layer of dielectric material on a semiconductor surface, the disposed dielectric material layer having at least one aperture;
b) depositing a metal layer over the dielectric material layer, wherein the at least one aperture connects a portion of the metal layer to a portion of the semiconductor layer to thereby form a Schottky diode active area; and
c) welding an interconnect to the metal layer such that the interconnect overlaps a portion of the metal layer outside the active area and such that the dielectric material outside the active area provides protection against welding-related diffusion in the semiconductor layer.

15. (canceled)

16. (canceled)

17. (canceled)

18. The solar cell/bypass diode structure of claim 29 wherein the dielectric material layer is comprised of one or more thin film materials having a thickness in the approximate range of two hundred (200) angstroms to one (1) micron.

19. The solar cell/bypass diode structure of claim 18 wherein the thin film material is silicon dioxide.

20. The solar cell/bypass diode structure of claim 18 wherein the thin film material is silicon monoxide.

21. The solar cell/bypass diode structure of claim 18 wherein the thin film material is silicon nitride.

22. The solar cell/bypass diode structure of claim 18 wherein the thin film material is polyimide.

23. The solar cell/bypass diode structure of claim 18 wherein the thin film material is aluminum oxide.

24. The solar cell/bypass diode structure of claim 18 wherein the thin film material is titanium dioxide.

25. The solar cell/bypass diode structure of claim 18 wherein the thin film material is tantulum pentoxide.

26. The solar cell/bypass diode structure of claim 29 further comprising a metal short connecting a portion of the semiconductor layer to the semiconductor substrate.

27. The solar cell/bypass diode structure of claim 29 further comprising a back metallization that is common to both the solar cell portion of the semiconductor substrate and to the Schottky diode portion of the semiconductor substrate.

28. A Schottky diode, comprising:
a semiconductor layer,
a metal layer;
a dielectric material interposed between the metal layer and the semiconductor layer,
an aperture in the dielectric material that connects the semiconductor layer and the metal layer through the dielectric material, the aperture defining an active area between the metal layer and the semiconductor layer; and
an interconnect having a weld area overlapping, and welded to, a first portion of the metal layer, said weld area overlapping the dielectric material outside the active area to provide protection against welding-related diffusion in the semiconductor layer.

29. A solar cell/bypass diode structure, comprising:
a solar cell disposed on a first portion of a semiconductor substrate;
a semiconductor layer disposed on a second portion of the semiconductor substrate;
a dielectric material layer having at least one aperture disposed on the semiconductor layer,
a metal layer disposed on the dielectric material layer, wherein the at least one aperture connects a portion of the metal layer to a portion of the semiconductor layer to thereby form a Schottky diode active area, and wherein the Schottky diode active area is configured as a bypass diode in parallel reverse polarity with the solar cell; and
an interconnect having a weld area overlapping, and welded to, a first portion of the metal layer, said weld area overlapping the dielectric material outside the active area to provide protection against welding-related diffusion in the semiconductor layer.
